(19) United States
(12) Patent Application Publication
(10) Pub. No.: US 2025/0255080 A1
(43) Pub. Date: Aug. 7, 2025

(54) OPTOELECTRONIC DEVICE

(71) Applicant: Lextar Electronics Corporation, Hsinchu City (TW)

(72) Inventors: Shiou-Yi KUO, Hsinchu City (TW); Jian-Chin LIANG, Hsinchu City (TW)

(21) Appl. No.: 19/008,351

(22) Filed: Jan. 2, 2025

(30) Foreign Application Priority Data
Feb. 5, 2024 (TW) 113104414

(51) Int. Cl. H10H 29/85; H01L 25/075; H10H 20/824; H10H 29/851

(52) U.S. Cl. CPC H10H 29/857; H01L 25/0753; H10H 20/824; H10H 29/8514

(57) ABSTRACT

The present disclosure provides an optoelectronic device including a base, a light-emitting chip, an interposer, a wavelength conversion member and a wall portion. The base includes a base portion and a conductive portion, and the conductive portion comprises a plurality of coupling surfaces. The base portion covers the conductive portion and exposes the coupling surfaces. The light-emitting chip and the interposer are provided on the base, and having a top surface. The interposer covers the light-emitting chip and exposes the top surface. The wavelength conversion member covers the light-emitting chip and the interposer, and the wavelength conversion member includes an emitting surface. The wall portion is provided on the base. The wall portion covers the interposer and the wavelength conversion member, and exposes the emitting surface of the wavelength conversion member. The emitting surface is parallel to the top surface, and perpendicular to the coupling surfaces.

### CROSS REFERENCE TO RELATED APPLICATIONS

This application claims priority of Taiwan Patent Application No. 113104414, filed on Feb. 5, 2024, and the content of the entirety of which is incorporated by reference herein.

### BACKGROUND OF THE DISCLOSURE

### Field of the Disclosure

The present disclosure relates to an optoelectronic device, and, in particular, to a side-emitting optoelectronic device.

### Description of the Related Art

Optoelectronic device is widely used in various fields such as backlighting, lighting, and sensing in the form of light sources. For backlight applications, in order to reduce the thickness of backlight modules, side-emitting light sources have emerged. Although the current side-emitting light sources have generally been adequate for their intended use, they have not been entirely satisfactory in all respects. Therefore, there are still some issues to be overcome regarding side-emitting light sources.

### BRIEF SUMMARY OF THE DISCLOSURE

According to the present disclosure, an optoelectronic device includes a base including a base portion and a conductive portion comprising a plurality of coupling surfaces. The base portion covers the conductive portion and exposes the coupling surfaces. A light-emitting chip is provided on the base, and having a top surface. An interposer is provided on the base. The interposer covers the light-emitting chip and exposes the top surface of the light-emitting chip. A wavelength conversion member covers the light-emitting chip and the interposer. The wavelength conversion member includes an emitting surface. A wall portion is provided on the base. The wall portion covers the interposer and the wavelength conversion member, and exposes the emitting surface of the wavelength conversion member. The emitting surface is parallel to the top surface, and perpendicular to the coupling surfaces.

According to the present disclosure, an optoelectronic device includes a base including a base portion and a conductive portion comprising a plurality of coupling surfaces. The base portion covers the conductive portion and exposes the coupling surfaces. A plurality of light-emitting chips is provided on the base, and having a plurality of top surfaces. The plurality of top surfaces belongs to the plurality of light-emitting chips, respectively. An interposer is provided on the base. The interposer covers the plurality of light-emitting chips and exposes the top surfaces. A wavelength conversion member covers the plurality of light-emitting chips and the interposer. The wavelength conversion member includes an emitting surface. A wall portion is provided on the base. The wall portion covers the interposer and the wavelength conversion member, and exposes the emitting surface. The emitting surface is parallel to the top surfaces, and perpendicular to the plurality of coupling surfaces.

According to the present disclosure, an optoelectronic device includes a base including a base portion and a conductive portion comprising a plurality of coupling surfaces. The base portion covers the conductive portion and exposes the plurality of coupling surfaces. A plurality of light-emitting chips is provided on the base, and having a plurality of top surfaces. The plurality of top surfaces belongs to the plurality of light-emitting chips, respectively. An interposer is provided on the base. The interposer covers the plurality of light-emitting chips and exposes the plurality of top surfaces. A plurality of wavelength conversion members covers the plurality of light-emitting chips and the interposer, and has a plurality of emitting surfaces. The plurality of emitting surfaces is arranged above the plurality of light-emitting chips, respectively. A wall portion is provided on the base. The wall portion covers the interposer and the wavelength conversion members, and exposes the plurality of emitting surfaces. The plurality of emitting surfaces is separated from each other by the wall portion. The plurality of emitting surfaces is parallel to the plurality of top surfaces, and perpendicular to the plurality of coupling surfaces.

### BRIEF DESCRIPTION OF THE DRAWINGS

FIG. 1A is a schematic diagram showing a perspective view of an optoelectronic device according to some embodiments of the present disclosure.

FIG. 1B is a schematic diagram showing a cross-sectional view along the line AA of FIG. 1A according to some embodiments of the present disclosure.

FIG. 1C is a schematic diagram showing the application of an optoelectronic device according to some embodiments of the present disclosure.

FIG. 2 is a schematic diagram showing a cross-sectional view of an optoelectronic device according to some embodiments of the present disclosure.

FIG. 3 is a schematic diagram showing a cross-sectional view of an optoelectronic device according to some embodiments of the present disclosure.

FIG. 4A is a schematic diagram showing a perspective view of an optoelectronic device according to some embodiments of the present disclosure.

FIG. 4B is a schematic diagram showing a cross-sectional view along the line BB of FIG. 4A according to some embodiments of the present disclosure.

### DETAILED DESCRIPTION OF THE DISCLOSURE

The following disclosure provides many different embodiments, or examples, for implementing different components of the provided subject matter. Specific examples of components and arrangements are described below to simplify the illustration of the present disclosure. These are, of course, merely examples and are not intended to limit the present disclosure. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not indicate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The component may be otherwise oriented (rotated 90 degrees or at other orientations) and the spatially relative descriptors used herein may likewise be interpreted accordingly.

In the present disclosure, the terms “about”, “substantially”, or the like, represents within 10%, 5%, 3%, 2%, 1%, or 0.5%, of a given value or range. The given value herein is an approximate value, that is, even though there is no specific description of “about” or “substantially”, the given value implicitly includes the meaning of “about” or “substantially”.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the disclosure and the background or the context of the disclosure, and should not be interpreted in an idealized or overly formal manner unless so defined.

It should be noted that the technical features in different embodiments described in the following can be replaced, recombined, or mixed with one another to constitute another embodiment without departing from the spirit of the present disclosure.

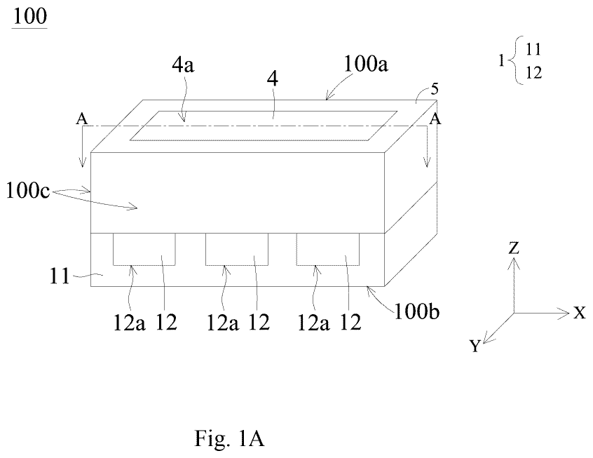

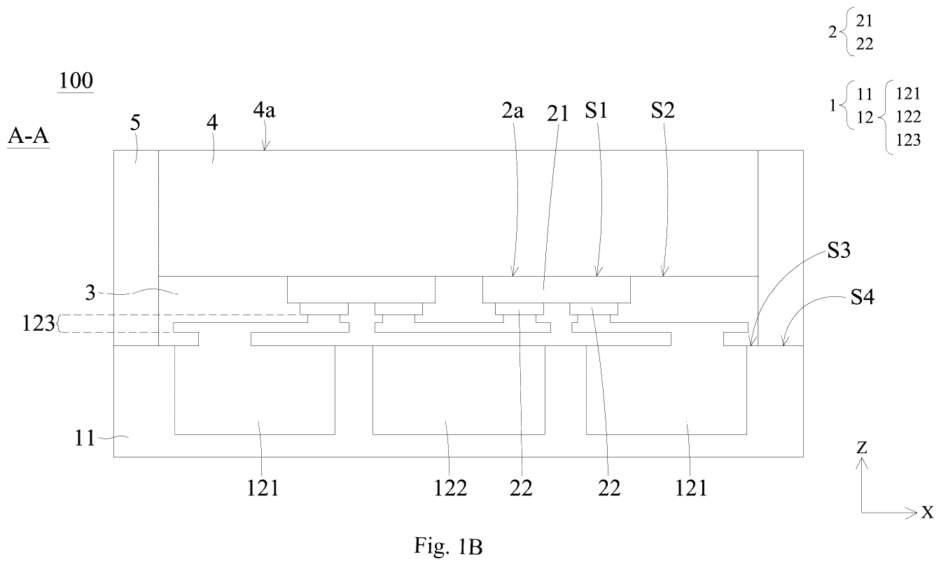

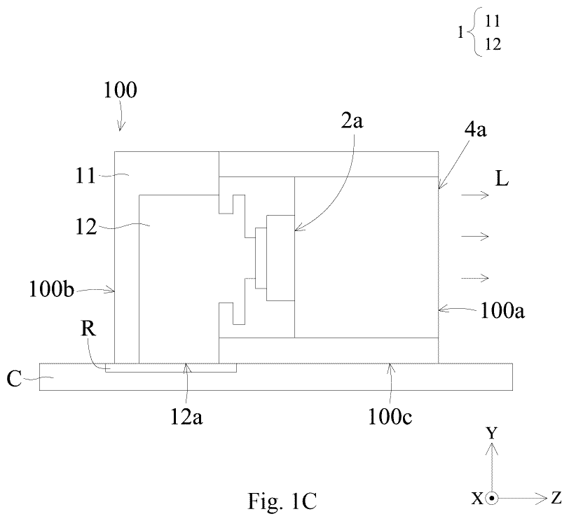

FIG. 1A is a schematic diagram showing a perspective view of an optoelectronic device 100, and FIG. 1B is a schematic diagram showing a cross-sectional view along the line AA of FIG. 1A according to some embodiments of the present disclosure. Please referring to FIG. 1A and FIG. 1B, the optoelectronic device 100 includes a base 1, a light-emitting chip 2, an interposer 3, a wavelength conversion member 4, and a wall portion 5.

The base 1 includes a base portion 11 and a conductive portion 12. The conductive portion 12 contains a plurality of coupling surfaces 12a. The base portion 11 covers the conductive portion 12 and exposes the coupling surfaces 12a of the conductive portion 12. In other words, the base portion 11 surrounds but not covers the coupling surfaces 12a. In some embodiments, a surface of the base portion 11 surrounds the coupling surfaces 12a is flush with the coupling surfaces 12a. In some embodiments, the conductive portion 12 contains an electrical-conductive part 121, an thermal-conductive part 122, and a connecting part 123, the electrical-conductive part 121 is used to electrically connect the optoelectronic device 100 to an external power source; the thermal-conductive part 122 is used to improve the heat dissipation of the optoelectronic device 100; the connecting part 123 is used to form an internal circuit of the optoelectronic device 100, for example, to electrically connect the electrical-conductive part 121 and the light-emitting chip 2 and/or to electrically connect the plurality of light-emitting chips 2 with each other. In some embodiments, the conductive portion 12 contains a plurality of electrical-conductive parts 121 and a plurality of connecting parts 123, the number of the connecting parts 123 may be greater or equal to the number of the electrical-conductive parts 121. In some embodiments, the conductive portion 12 may include one or more thermal-conductive parts 122. In some embodiments, the conductive portion 12 may include no thermal-conductive part 122. In some embodiments, the plurality of coupling surfaces 12a are composed of the electrical-conductive parts 121 and/or the thermal-conductive parts 122.

In some embodiments, the electrical-conductive part 121 and the thermal-conductive part 122 are, for example, cylinders or blocks with a certain thickness such as 5 μm to 100 μm. The connecting part 123 may be, for example, a film layer with a thickness smaller than that of the electrical-conductive part 121 and the thermal-conductive part 122. When the thickness of the electrical-conductive part 121 and the thermal-conductive part 122 is less than 5 μm, the area of the coupling surfaces 12a will be reduced, which may increase the difficulty of the subsequent bonding process; when the thickness of the electrical-conductive part 121 and the thermal-conductive part 122 is greater than 100 μm, the overall size of the optoelectronic device 100 will be significantly increased, which is unfavorable to the applications of slim apparatus.

In some embodiments, the base portion 11 includes an insulating material. The insulating material may be, for example, polyimide (PI), epoxy resin, silicone resin, other suitable materials, or the combinations thereof. In some embodiments, fillers can be added to the insulating material of the base portion 11 so that the base portion 11 can shield, absorb, or reflect the light emitted from the light-emitting chip 2. The fillers may be, for example, titanium oxide (TiOₓ), silicon oxide (SiOₓ), pigments, other suitable materials, or combinations thereof. In some embodiments, the conductive portion 12 includes a conductive material that is able to conduct electricity or heat. The conductive material may include metal, metal compounds, other suitable materials, or the combinations thereof. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), alloys of the aforementioned materials or combinations thereof. The metal compound may be tantalum nitride (TaN), titanium nitride (TiN), tungsten silicide (WSi₂), etc. In some embodiments, the electrical-conductive part 121, the thermal-conductive part 122 and the connecting part 123 may be made of the same or different materials. For example, the electrical-conductive part 121 may be made of the same material as the thermal-conductive part 122, and the electrical-conductive part 121 may be made of the material different with the connecting part 123.

In some embodiments, the base portion 11 can be formed through coating, molding, other suitable methods, or a combination thereof, and the conductive portion 12 can be formed through a deposition process (e.g. evaporation, sputtering, and plating), screen printing, vacuum spraying, other suitable methods or a combination thereof. In some embodiments, the electrical-conductive part 121 and the thermal-conductive part 122 can be formed in the same process to simplify the manufacturing procedure. In this embodiment, the base portion 11 can be an epoxy molding compound (EMC) with black pigment added, the electrical-conductive part 121 and the thermal-conductive part 122 of the conductive portion 12 can be copper (Cu) blocks formed by plating, and the connecting part 123 may be a metal film stack formed of a Cr/Pt/Au stack or a Ti/Cu/Ti stack by sputtering. Specifically, the light-emitting chip 2 is electrically connected to the electrical-conductive part 121 through the connecting part 123 formed by the metal deposition process, and the light-emitting chip 2 is supported by the base 1 formed from the combination of the base portion 11, the electrical-conductive part 121 in the form of Cu block with a sufficient thickness, and the thermal-conductive part 122 in the form of a Cu block with a sufficient thickness. Compare to the general method of first forming a circuit on a supporting substrate and then electrically connecting the light-emitting chip to the supporting substrate through processes such as welding, eutectic or bonding, the embodiment of the present disclosure not only can achieve a high-precision electrical route, but also can reduce the overall size of the device effectively and meet the thinning requirement.

The light-emitting chip 2 is located on the base 1 and can emit light from the top surface 2a by supplying electricity. The light-emitting chip 2 is, for example, a light-emitting diode (LED) chip or a laser diode (LD) chip. The light-emitting chip 2 includes a light-emitting stack 21 and an electrode pair 22. The electrode pair 22 is located on a side of the light-emitting stack 21 facing the base 1. That is, the electrode pair 22 is located on a side of the light-emitting chip 2 opposite to the top surface 2a. In some embodiments, the electrode pairs 22 have different characteristics of electricity. For example, when one of the electrode pair 22 is P-type, the other one of the electrode pair 22 is N-type.

In some embodiments, the light-emitting stack 21 may include III-V compound materials, such as aluminum (Al), gallium (Ga), arsenic (As), phosphorus (P), indium (In) or nitrogen (N). Specifically, in some embodiments, the III-V compound materials can be binary compound semiconductors (e.g., GaAs, GaP, GaN or InP), ternary compound semiconductors (e.g., InGaAs, AlGaAs, GaInP, AlInP, InGaN or AlGaN) or a quaternary compound semiconductor (e.g., AlGaInAs, AlGaInP, AlInGaN, InGaAsP, InGaAsN or AlGaAsP). In some embodiments, the top surface 2a of the light-emitting chip 2 includes III-V compound materials.

In some embodiments, the electrode pair 22 includes conductive materials, such as metals, nitrides, oxides, similar materials, or combinations thereof. For example, metals may include gold (Au), nickel (Ni), platinum (Pt), palladium (Pd), iridium (Ir), titanium (Ti), chromium (Cr), tungsten (W), aluminum (Al), copper (Cu), beryllium (Be), germanium (Ge), zinc (Zn), tin (Sn), the alloys or combinations thereof. The nitride may include titanium nitride (TiN), and the oxide may include indium tin oxide (ITO) or indium zinc oxide (IZO).

In some embodiments, the light-emitting stack 21 can be formed on a growth substrate (not shown) first through an epitaxial growth process, such as, metal-organic chemical vapor deposition (MOCVD), hydride vapor phase epitaxy, HVPE), molecular beam epitaxy (MBE), liquid-phase epitaxy (LPE), vapor phase epitaxy (VPE) or other suitable processes. Then, the electrode pair 22 is formed on the light-emitting stack 21 through a process such as evaporation or sputtering, and finally remove the growth substrate to form the light-emitting chip 2. In other words, the light-emitting chip 2 does not include a substrate, and the top surface 2a of the light-emitting chip 2 is composed of the light-emitting stack 21.

In some embodiments, the optoelectronic device 100 may include one or more light-emitting chips 2. The light-emitting chips 2 can be electrically independent from each other, or the light-emitting chips 2 can be connected to each other through the connecting part 123 of the conductive portion 12. Specifically, when the light-emitting chips 2 are electrically independent from each other, the light-emitting chips 2 are respectively connected to different connecting parts 123 and electrical-conductive parts 121. The number of the electrical-conductive parts 121 and the connecting parts 123 will be respectively fit to the number of the electrode pairs 22 of the light-emitting chips 2. Specifically, one electrode pair 22 (two electrodes) will be connected to the two electrical-conductive parts 121 through two connecting parts 123. Since the light-emitting chips 2 are electrically independent from each other, they can be controlled separately. When the light-emitting chips 2 are electrically connected, at least two light-emitting chips 2 are connected to the same one of the connecting parts 123, such as connecting in series or in parallel, and the at least two light-emitting chips are respectively connected to the corresponding one of the electrical-conductive parts 121 through the corresponding one of the connection parts 123. Therefore, the number of the electrical-conductive parts 121 and the connecting parts 123 can be reduced, the design of the circuit and the complexity of subsequent external electrical connection can be simplified.

The interposer 3 is provided on the base 1. The interposer 3 covers the light-emitting chip 2 and exposes the top surface 2a of the light-emitting chip 2. In other words, the interposer 3 does not cover the top surface 2a of the light-emitting chip 2. In some embodiments, a surface of the interposer 3 surrounding the top surface 2a of the light-emitting chip 2 may be flush with the top surface 2a of the light-emitting chip 2. In some embodiments, the interposer 3 includes an insulating material. The insulating material is, for example, epoxy resin, polyimide (PI), polybenzoxazole (PBO), silicone, or silicon oxide. (SiOₓ), silicon nitride (SiNₓ) or combinations thereof. In some embodiments, the transmittance of the light emitted by the light-emitting chip 2 to the interposer 3 can range from 5% to 90%, such as 5% to 10%, 10% to 20%, 20% to 30%, 30% to 40%, 40% to 50%, 50% to 60%, 60% to 70%, 70% to 80%, 80% to 90%, or any range of the above values. In some embodiments, the interposer 3 is located on the base 1 and exposes the peripheral surface of the base 1, that is, the interposer 3 does not completely cover the substrate 1, as shown in FIG. 1B.

In some embodiments, the connecting part 123 of the conductive portion 12 may be embedded in the interposer 3. In some embodiments, the electrical-conductive part 121 of the conductive portion 12 can extend toward the light-emitting chip 2 and penetrate into the interposer 3 to be electrically connected to the corresponding one of the connecting parts 123. The position of the electrical contact of the light-emitting chip 2 (i.e., the electrode pair 22) can be adjusted and extended to a desired position (i.e., the electrical-conductive part 121) through the connecting part 123. The extending direction of the electrical-conductive part 121 can be vertical and/or horizontal.

The wavelength conversion member 4 covers the light-emitting chip 2 and the interposer 3, and is used to convert the wavelength of the light emitted from the light-emitting chip 2. The light after converting by the wavelength conversion member 4 is mainly emitted from the emitting surface 4a of the wavelength conversion member 4. In some embodiments, the transmittance of the light emitted by the light-emitting chip 2 to the wavelength conversion member 4 may be, for example, 80%, 85%, 90%, 95%, 100% or any range of the above values. In some embodiments, the transmittance of the light emitted by the light-emitting chip 2 to the wavelength conversion member 4 is greater than the transmittance to the interposer 3. In some embodiments, the wavelength conversion member 4 includes a wavelength conversion material, such as phosphor or quantum dots (QD). The wavelength converter 4 can be formed by coating, molding, other suitable methods, or a combination thereof. In some embodiments, the light-emitting surface 4a of the wavelength conversion member 4 is parallel to the top surface 2a of the light-emitting chip 2. In some embodiments, the side wall of the wavelength converter 4 is flush with the side wall of the interposer 3.

The wall portion 5 is located on the base 1. The wall portion 5 covers the interposer 3 and the wavelength conversion member 4, and exposes the emitting surface 4a of the wavelength conversion member 4. In other words, the wall portion 5 does not cover the emitting surface 4a of the wavelength conversion member 4. In some embodiments, the surface of the wall portion 5 surrounding the emitting surface 4a is flush with the emitting surface 4a. In some embodiments, the wall portion 5 includes an insulating material. The insulating material may be, for example, polyimide (PI), epoxy resin, silicone resin, other suitable materials, or the combinations thereof. In some embodiments, fillers can be added to the insulating material of the wall portion 5 so that the wall portion 5 is opaque. For example, the wall portion 5 can shield, absorb, or reflect the light emitted from the light-emitting chip 2. The fillers may be, for example, titanium oxide (TiOₓ), silicon oxide (SiOₓ), pigments, other suitable materials, or combinations thereof. In this embodiment, the wall portion 5 is an epoxy molding compound (EMC) with white color due to the fillers of titanium oxide (TiOx) are added in. In some embodiments, the side wall of the wall portion 5 is flush with the side wall of the interposer 3.

In some embodiments, the wavelength conversion member 4 directly contacts the light-emitting chip 2 and the interposer 3. Specifically, the wavelength conversion member 4 directly contacts the emitting surface 2a of the light-emitting chip 2 and the interposer 3. The horizontal interface between the wavelength conversion member 4 and the emitting surface 2a is the first contact surface S1, and the horizontal interface between the wavelength conversion member 4 and the interposer 3 is the second contact surface S2. In some embodiments, the first contact surface S1 is flush with the second contact surface S2.

In some embodiments, the base 1 directly contacts the interposer 3 and the wall portion 5. Specifically, the base portion 11 of the base 1 directly contacts the interposer 3 and the wall portion 5. The horizontal interface between the base portion 11 and the interposer 3 is the third contact surface S3, and the horizontal interface between the base portion 11 and the wall portion 5 is the fourth contact surface S4. In some embodiments, the third contact surface S3 is flush with the fourth contact surface S4.

As shown in FIG. 1A, the optoelectronic device 100 includes an upper surface 100a, a lower surface 100b, and a plurality of side surface 100c between the upper surface 100a and the lower surface 100b. In other words, the upper surface 100a and the lower surface 100b are opposite arranged and connected to each other through the side surfaces 100c. In some embodiments, the upper surface 100a includes the emitting surface 4a of the wavelength conversion member 4. Specifically, the upper surface 100a is constituted of the wavelength conversion member 4 and the wall portion 5, and the emitting surface 4a of the wavelength conversion member 4 is surrounded by the wall portion 5. In some embodiments, the lower surface 100b includes the base 1. Specifically, the lower surface 100b is constituted of the base portion 11 of the base 1. In other words, the entire lower surface 100b is made of the base portion 11. In some embodiments, the side surfaces 100c include the base 1 and the wall portion 5. One of the side surfaces 100c includes the coupling surfaces 12a of the conductive portion 12, while the others of the side surfaces 100c do not include any coupling surfaces 12a of the conductive portion 12. Specifically, the one of the side surfaces 100c including coupling surfaces 12a is constituted of the base portion 11, the conductive portions 12 and the wall portion 5, while the others of the side surfaces 100c not including coupling surfaces 12a are constituted of the base portion 11 and the wall portion 5.

In some embodiments, the coupling surfaces 12a can be formed at the side surface 100c through a cutting process. Specifically, in the manufacturing process of forming the base 1, the conductive portions 12 are wrapped by the base portion 11 first, and then a part of the base portion 11 is removed through the cutting process to forming the coupling surfaces 12a at the predetermined one of the side surfaces 100c. Therefore, the coupling surfaces 12a located at the predetermined one of the side surfaces 100c are flush with the surface of the base portion 11 and the surface of the wall portion 5 surrounding the coupling surfaces 12a, as shown in FIG. 1A.

FIG. 1C is a schematic diagram showing the application of an optoelectronic device 100 according to some embodiments of the present disclosure. As shown in FIG. 1C, one of the side surfaces 100c of the optoelectronics device 100 is connected to an external circuit R on a carrier C, and the optoelectronic device 100 emits light L from the upper surface 100a. Specifically, the optoelectronic device 100 is electrically connected to the external circuit R through the coupling surfaces 12a at the side surface 100c, and the light L emitted by the optoelectronic device 100 is emitted from the emitting surface 4a at the upper surface 100a. In other words, the coupling surfaces 12a are not opposite to the emitting surface 4a. Therefore, when the optoelectronic device 100 is bonded to the carrier C, the light L of the optoelectronic device 100 emits in a lateral direction. Moreover, since the lower surface 100b and the side surfaces 100c of the optoelectronic device 100 do not include the emitting surface 4a, and the emitting surface 4a located at the upper surface 100a is surrounded by the opaque wall portion 5, the light extraction efficiency can be enhanced and the emission light can be more concentrated. Besides, due to the light emitted by the light-emitting chip 2 is mainly emitted from the top surface 2a, and the top surface 2a faces to and directly contacts the wavelength conversion member 4, the light emitted by the light-emitting chip 2 can directly enter the wavelength conversion member 4, and directly emit from the emitting surface 4a after passing through the wavelength conversion member 4. That means, the light does not pass through any medium other than the wavelength conversion member 4 in the light traveling path, thus the light extraction loss can be further reduced.

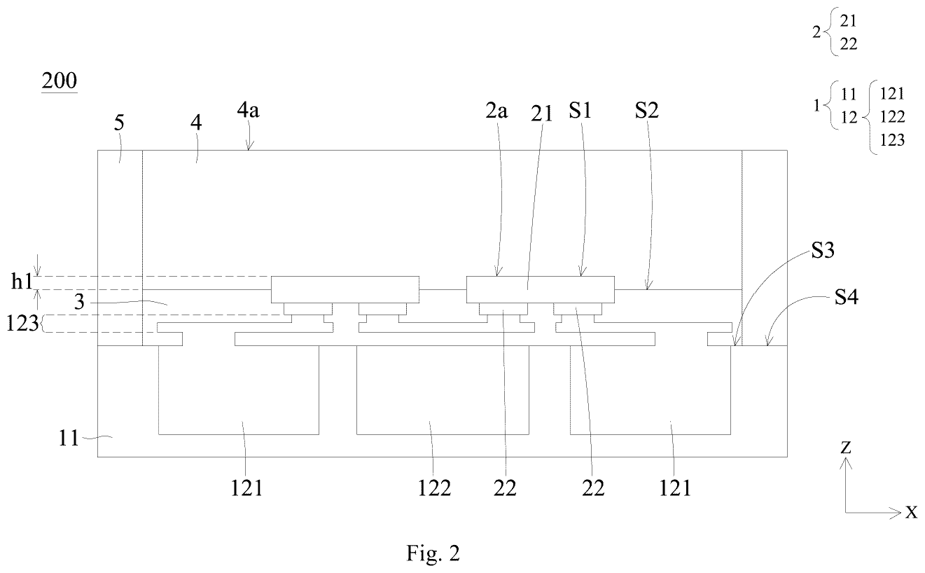

FIG. 2 is a schematic diagram showing a cross-sectional view of an optoelectronic device 200 according to some embodiments of the present disclosure. In order to facilitate the comparison of the differences with the above-mentioned embodiments and simplify the description, the identical elements are marked with the same symbols in the following embodiments, and focus on describing the differences between the embodiments without repeating the repetitive parts. The difference between the optoelectronic device 200 and the optoelectronic device 100 is that the first contact surface S1 is not flush with the second contact surface S2. That is, there is a distance h1 between the first contact surface S1 and the second contact surface S2 in the vertical direction. The range of the distance h1 is, for example, greater than 0 micrometer (μm) and less than 10 micrometer (μm). In this embodiment, the second contact surface S2 is closer to the base 1 than the first contact surface S1. In other words, the wavelength conversion member 4 further extends toward the base 1, and contacts not only the top surface 2a but also the other surfaces of the light-emitting chip 2, as shown in FIG. 2A. Since the contact area between the wavelength conversion member 4 and the light-emitting chip 2 is increased, that means the range in which the light emitted by the light-emitting chip 2 directly enters the wavelength conversion member 4 is also increased, thereby improving the wavelength conversion efficiency.

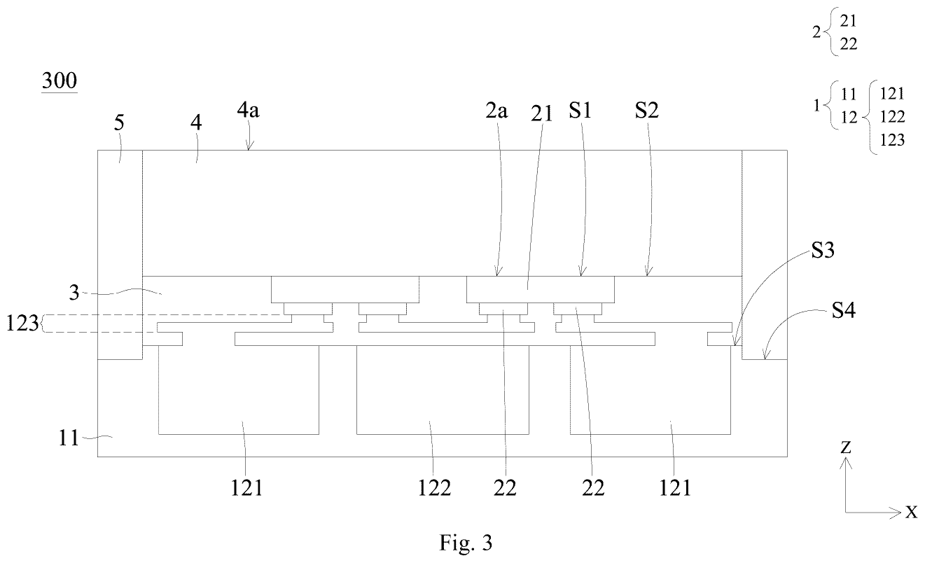

FIG. 3 is a schematic diagram showing a cross-sectional view of an optoelectronic device 300 according to some embodiments of the present disclosure. The difference between the optoelectronic device 300 and the optoelectronic device 100 is that the third contact surface S3 is not flush with the fourth contact surface S4. That is, there is a distance h2 between the third contact surface S3 and the fourth contact surface S4 in the vertical direction. The range of the distance h2 is, for example, greater than 0 μm and less than 5 μm. In this embodiment, the fourth contact surface S4 is further to the wavelength conversion member 4 than the third contact surface S3. In other words, the contact area between the wall portion 5 and the base portion 11 is increased, as shown in FIG. 3. Since the contact area between the wall portion 5 and the base portion 11 is increased, the adhesion between the wall portion 5 and the base portion 11 is improved and the reliability risk caused by the poor adhesion between the wall portion 5 and the base portion 11 is reduced.

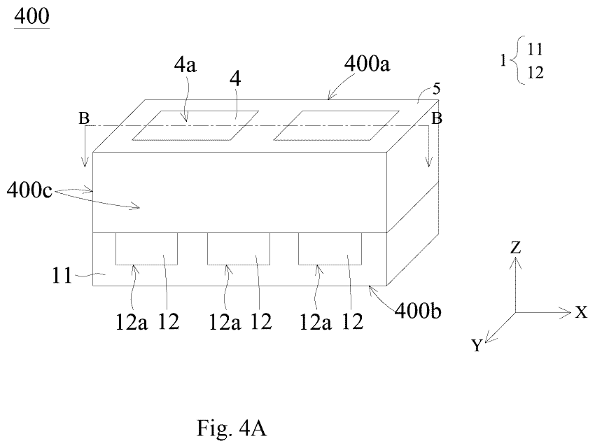

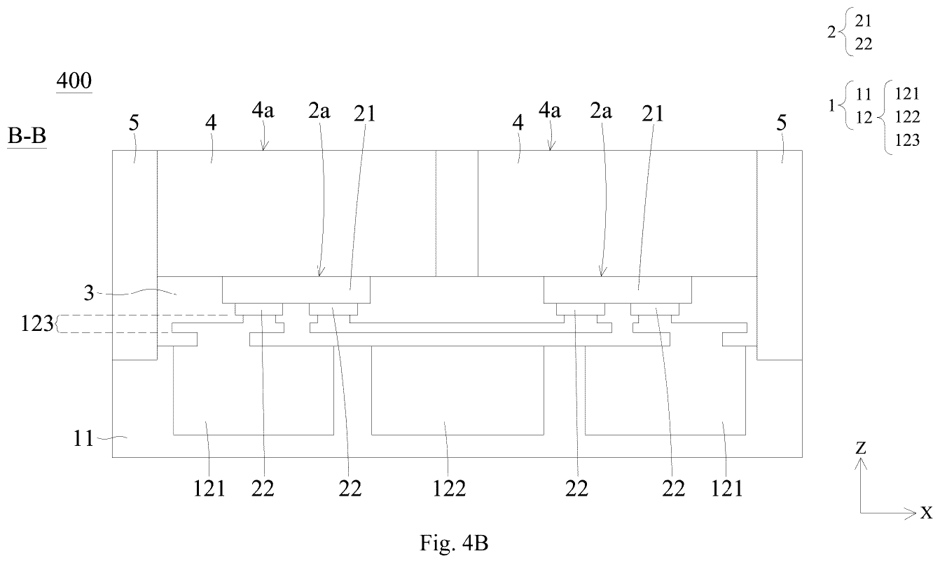

FIG. 4A and 4B is schematic diagrams respectively showing a perspective view and a cross-sectional view of an optoelectronic device 400 according to some embodiments of the present disclosure. The difference between the optoelectronic device 400 and the optoelectronic device 100 is that, the optoelectronic device 400 includes a plurality of light-emitting chips 2 and a plurality of wavelength conversion members 4, the wavelength conversion members 4 respectively cover the corresponding one of the light-emitting chips 2, and each of the wavelength conversion members 4 has a emitting surface 4a. As shown in FIG. 4A, the upper surface 4a of the optoelectronic device 400 includes a plurality of emitting surfaces 4a, and the emitting surfaces 4a are respectively surrounded by the wall portion 5. In other words, the emitting surfaces 4a are separated from each other by through the wall portion 5. In some embodiments, the emitting surfaces 4a are flush with each other.

Embodiments of the present disclosure provide an optoelectronic device, by combining the metal block and base portion to form the base and forming the internal electrical connection through metal deposition process, can achieve a high-precision electrical route allows to increase the number of light-emitting chips per unit area during manufacturing process. In addition, the wall portion and the wavelength conversion member are formed using a molding process and the coupling surface of the metal block are exposed through cutting one of the sidewalls of the optoelectronic device so that the emitting surface and the coupling surface of the optoelectronic device are perpendicular to each other, which can effectively reduce the thickness of the backlight module using thereof.

The elements in the embodiments of the present disclosure can be exchanged or used together as long as they do not violate or conflict to the spirit of the disclosure. In addition, the protection scope of the present disclosure includes but not limits to the processes, machines, manufacturing, material compositions, devices, methods and steps in the specific embodiments described in the specification. Anyone of ordinary skill in the art can refer to the disclosure content of the present disclosure to understand that processes, machines, manufacturing, material compositions, devices, methods and steps currently or developed in the future. Anything that can perform substantially the same functions or obtain substantially the same results in the embodiments described herein may be used in accordance with the present disclosure. Any embodiment or claim of the present disclosure does not need to achieve all the purposes, advantages and/or features disclosed in the present disclosure.

Several embodiments are described above so that those with ordinary skill in the art can better understand the viewpoints of the disclosed embodiments. It should be understood by those of ordinary skill in the art that other processes and structures can be designed or modified based on the embodiments of the present disclosure to achieve the same purposes and/or advantages as the embodiments introduced here. It should also be understood by those of ordinary skill in the art that such equivalent processes and structures do not deviate from the spirit and scope of the present disclosure, and can be used for various purposes, such as changes, without departing from the spirit and scope of the present disclosure. Such changes, replacements and substitutions.

Although the embodiments of the present disclosure have been described in detail, the present disclosure is not limited to specific embodiments, and various modifications and variations can be made within the spirit and scope of the disclosure described in the claims. Therefore, the scope for protecting the present disclosure should be defined according to the scope of the appended claims.

What is claimed is:

1. An optoelectronic device, comprising:
a base including a conductive portion comprising a plurality of coupling surfaces, and a base portion which covers the conductive portion and exposes the plurality of coupling surfaces;
a light-emitting chip provided on the base, and having a top surface;
an interposer provided on the base, covering the light-emitting chip, and exposing the top surface;
a wavelength conversion member covering the light-emitting chip and the interposer, and having an emitting surface; and
a wall portion provided on the base covering the interposer and the wavelength conversion member, and exposing the emitting surface,
wherein the emitting surface is parallel to the top surface, and perpendicular to the plurality of coupling surfaces.

2. The optoelectronic device as claimed in claim 1, wherein the optoelectronic device has an upper surface, a lower surface opposite to the upper surface, and a plurality of side surfaces arranged between the upper surface and the lower surface, the plurality of side surfaces has only one side surface wherein the plurality of coupling surfaces is arranged.

3. The optoelectronic device as claimed in claim 2, wherein the only one side surface comprises a surface of the base portion, the plurality of coupling surfaces of the conductive portion, and a surface of the wall portion.

4. The optoelectronic device as claimed in claim 2, wherein the lower surface comprises a surface of the base portion, and the upper surface comprises a surface of the wavelength conversion member and a surface of the wall portion.

5. The optoelectronic device as claimed in claim 1, wherein the wavelength conversion member directly contacts the top surface of the light-emitting chip.

6. The optoelectronic device as claimed in claim 5, wherein the wavelength conversion member further directly contacts a lateral surface of the light-emitting chip.

7. The optoelectronic device as claimed in claim 1, wherein the light-emitting chip includes III-V compound material.

8. The optoelectronic device as claimed in claim 1, wherein the interposer and the wall portion have bottom surfaces which are not flush with each other.

9. An optoelectronic device, comprising:
a base including a conductive portion which comprises a plurality of coupling surfaces, and a base portion which covers the conductive portion and exposes the plurality of coupling surfaces;
a plurality of light-emitting chips provided on the base, and having a plurality of top surfaces, wherein the plurality of top surfaces belongs to the plurality of light-emitting chips, respectively;
an interposer provided on the base, covering the plurality of light-emitting chips, and exposing the plurality of top surfaces;
a wavelength conversion member covering the plurality of light-emitting chips and the interposer, and having an emitting surface; and
a wall portion provided on the base, covering the interposer and the wavelength conversion member, and exposing the emitting surface,
wherein the emitting surface is parallel to the plurality of top surfaces, and perpendicular to the plurality of coupling surfaces.

10. The optoelectronic device as claimed in claim 9, wherein the optoelectronic device has an upper surface, a lower surface opposite to the upper surface, and a plurality of side surfaces arranged between the upper surface and the lower surface, the plurality of side surfaces has only one side surface wherein the plurality of coupling surfaces is arranged.

11. The optoelectronic device as claimed in claim 10, wherein the only one side surface comprises a surface of the base portion, the plurality of coupling surfaces of the conductive portion, and a surface of the wall portion.

12. The optoelectronic device as claimed in claim 10, wherein the lower surface comprises a surface of the base portion, and the upper surface comprises a surface of the wavelength conversion member and a surface of the wall portion.

13. The optoelectronic device as claimed in claim 9, wherein the plurality of light-emitting chips each includes III-V compound material.

14. The optoelectronic device as claimed in claim 9, wherein the interposer and the wall portion have bottom surfaces which are not flush with each other.

15. An optoelectronic device, comprising:
a base including a conductive portion comprising a plurality of coupling surfaces, and a base portion which covers the conductive portion and exposes the plurality of coupling surfaces;
a plurality of light-emitting chips provided on the base, and having a plurality of top surfaces, wherein the plurality of top surfaces belongs to the plurality of light-emitting chips, respectively;
an interposer provided on the base, covering the plurality of light-emitting chips, and exposing the plurality of top surfaces;
a plurality of wavelength conversion members covering the plurality of light-emitting chips and the interposer, and having a plurality of emitting surfaces, wherein the plurality of emitting surfaces is arranged above the plurality of light-emitting chips, respectively; and
a wall portion provided on the base, covering the interposer and the plurality of wavelength conversion members, and exposing the plurality of emitting surfaces which is separated from each other by the wall portion;
wherein the plurality of emitting surfaces is parallel to the plurality of top surfaces, and perpendicular to the plurality of coupling surfaces.

16. The optoelectronic device as claimed in claim 15, wherein the optoelectronic device has an upper surface, a lower surface opposite to the upper surface, and a plurality of side surfaces arranged between the upper surface and the lower surface, the plurality of side surfaces has only one side surface wherein the plurality of coupling surfaces is arranged.

17. The optoelectronic device as claimed in claim 16, wherein the only one side surface comprises a surface of the base portion, the plurality of coupling surfaces of the conductive portion, and a surface of the wall portion.

18. The optoelectronic device as claimed in claim 16, wherein the lower surface comprises a surface of the base portion, and the upper surface comprises a surface of the plurality of wavelength conversion members, and a surface of the wall portion.

19. The optoelectronic device as claimed in claim 15, wherein the plurality of light-emitting chips each includes III-V compound material.

20. The optoelectronic device as claimed in claim 15, wherein the interposer and the wall portion have bottom surfaces which are not flush with each other.
